(19) United States
(12) Patent Application Publication
(10) Pub. No.: US 2010/0193354 A1
(43) Pub. Date: Aug. 5, 2010

(54) MAGNETRON SPUTTERING CATHODE

(75) Inventor: GUAN-YEU CHU, Taichung (TW)

Correspondence Address: WPAT, PC;INTELLECTUAL PROPERTY ATTORNEYS, 7225 BEVERLY ST., ANNANDALE, VA, 22003, US

(73) Assignee: WINTEK CORPORATION, Taichung (TW)

(21) Appl. No.: 12/698,391

(22) Filed: Feb. 2, 2010

(30) Foreign Application Priority Data
Feb. 3, 2009 (TW) 098103393

(51) Int. Cl. C23C 14/34

(52) U.S. Cl. 204/298.16

(57) ABSTRACT

A magnetron sputtering cathode, comprising: a metal tube being hollow; and a plurality of magnet units, disposed inside the metal tube forming a plurality of sputtering zones on the surface of the metal tube, each of the sputtering zones corresponding to a substrate; wherein, each sputtering zone is provided with a magnetic tunnel and the magnetic tunnels are configured to communicate with each other to form a closed loop for guiding electrons to circulate therein. Thus, by the use of only one aforesaid magnetron sputtering cathode, multiple substrates can be coated at the same time, the waste related to plasma usage can be prevented to reduce power and target loss, and the same time that the probability of depositing the sputtered target on the portion of the sputtering chamber at the back of the magnetron sputtering cathode is reduced and thus the efficiency of the target is increased.

### BACKGROUND OF THE INVENTION

1. Field of the Invention

The present invention generally relates to a magnetron sputtering cathode, and more particularly to a magnetron sputtering cathode with a metal tube comprising a plurality of sputtering zones so as to form thin films on multiple substrates without the waste of plasma and to reduce power and target loss. Moreover, the probability of depositing the sputtered target on the portion of the sputtering chamber at the back of the magnetron sputtering cathode is reduced and thus the efficiency of the target is increased.

2. Description of the Prior Art

Since the 90's, people have started to emphasize the development in multi-layered film formation, which has been going on for years and is widely used in application fields such as mechanical manufacture, the car industry, the mold industry, and aeronautic applications. In sputtering techniques, vacuum magnetron sputtering is widely used in decorative coatings and functional coatings for home appliances, watches, lamps, art works, toys, car lamp reflectors, cellular phone housings, equipments, plastics, glass, ceramic tiles, etc.

Please refer to FIG. 1 and FIG. 2 for a conventional cylindrical magnetron sputtering cathode. The magnetron sputtering cathode 10 comprises a hollow cylindrical metal tube 11, in which there are provided a plurality of magnet units 12 comprising a plurality of magnets 121 with magnetic south poles (S in FIG. 1) outwards from the metal tube 11 and a plurality of magnets 122 with magnetic north poles (N in FIG. 1) outwards from the metal tube 11. The magnets 121 with magnetic south poles oriented outwards from the metal tube 11 are disposed in parallel with the axis of the metal tube 11. The magnets 122 with magnetic north poles oriented outwards from the metal tube 11 are disposed surrounding the magnets 121 with magnetic south poles oriented outwards from the metal tube 11 so that a ring-shaped magnetic tunnel 14 is constructed by the magnets 121 and the magnets 122, as shown in FIG. 1. The zone of the ring-shaped magnetic tunnel 14 is regarded as a sputtering zone 13. The metal tube 11 is surrounded and covered by a target 15, which is a distance away from a substrate 20 corresponding to the magnetic tunnel 14. The magnetron sputtering cathode 10 and the substrate 20 are disposed in a reaction chamber 16. When a voltage is applied, electrons are driven by an electromagnetic field to move in a determined way along the magnetic tunnel 14. In the region 141 of magnetic field lines (as shown in FIG. 2), plasma is generated to sputter the target 15 so that the atoms/molecules of the target 15 are deposited on the substrate 20 to form a thin film.

Accordingly, the conventional magnetron sputtering cathode exhibits disadvantages such as:

1. Only a sputtering zone 13 is provided so that thin film deposition can only be performed on one substrate 20 in one process.

2. Since the magnet units 12 are disposed on one side of the metal tube 11, secondary plasma is generated on the portion of the metal tube 11 with no magnet units 12 (i.e., the portion on the other side of the region 141 of magnetic field lines) to cause power and target loss.

Some sputtered atoms/molecules of the target 15 are deposited on the chamber wall 161 at the back of the metal tube 11 (i.e., the portion of the metal tube 11 with no magnet units 12) to cause target loss.

### SUMMARY OF THE INVENTION

Accordingly, it is one object of the present invention to provide a magnetron sputtering cathode so that multiple substrates can be coated at the same time to prevent the waste related to secondary plasma and reduce power and target loss. Meanwhile, the probability of depositing the sputtered target on the portion of the sputtering chamber at the back of the magnetron sputtering cathode is reduced and thus the efficiency of the target is increased.

In order to achieve the foregoing object, the present invention provides a magnetron sputtering cathode, comprising: a metal tube being hollow; and a plurality of magnet units, disposed inside the metal tube for forming a plurality of sputtering zones on the surface of the metal tube, each of the sputtering zones corresponding to a substrate; wherein, each of the plurality of sputtering zones is provided with a magnetic tunnel and the magnetic tunnels are configured to communicate with each other to form a closed loop for guiding electrons to circulate therein.

### BRIEF DESCRIPTION OF THE DRAWINGS

The objects, spirits and advantages of various embodiments of the present invention will be readily understood by the accompanying drawings and detailed descriptions, wherein:

FIG. 1 is a structural diagram of a conventional magnetron sputtering cathode;

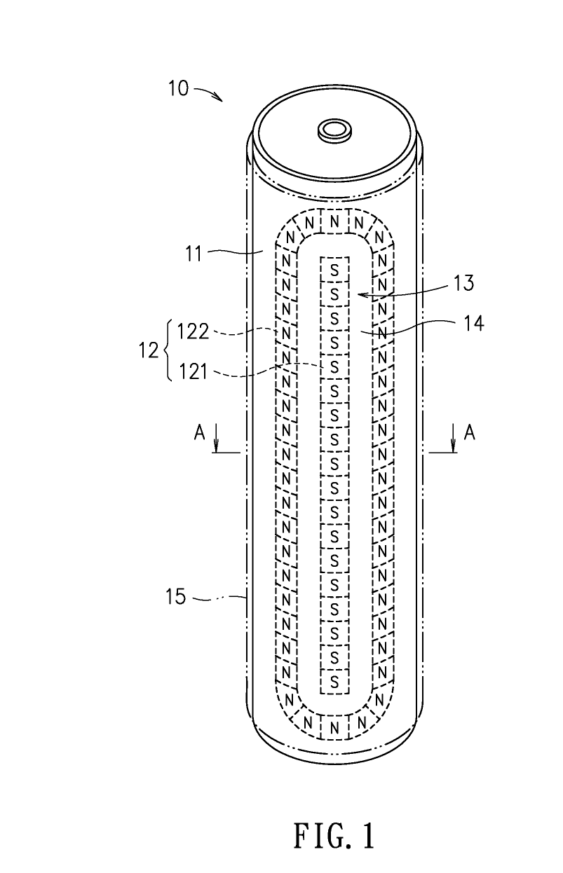

FIG. 2 is a cross-sectional view along A-A in FIG. 1, wherein a substrate is disposed in a reaction chamber;

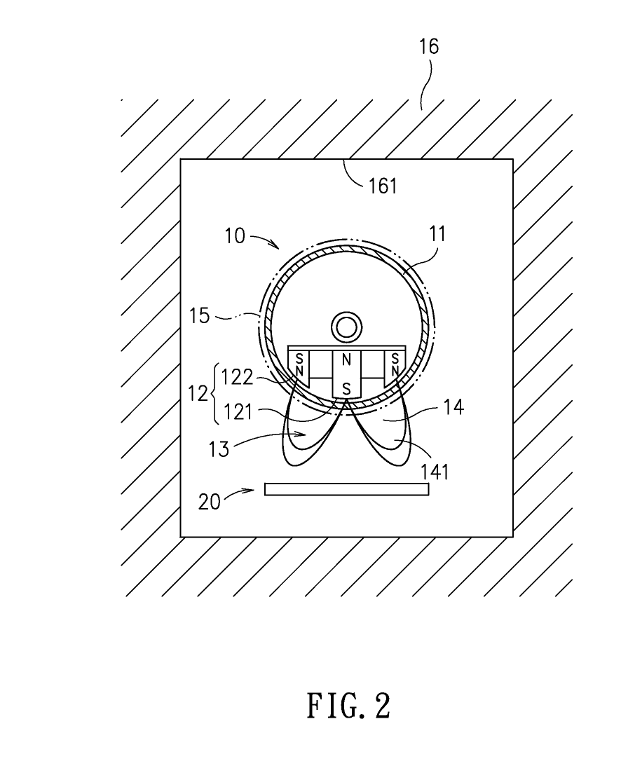

FIG. 3 is a 3-D view of a magnetron sputtering cathode according to one embodiment of the present invention;

FIG. 4 is an unfold diagram of a magnetic tunnel according to one embodiment in FIG. 3; and

FIG. 5 is a cross-sectional view along B-B in FIG. 3, wherein two substrates are disposed in a reaction chamber.

### DETAILED DESCRIPTION OF THE PREFERRED EMBODIMENT

The present invention can be exemplified by various embodiments as described hereinafter.

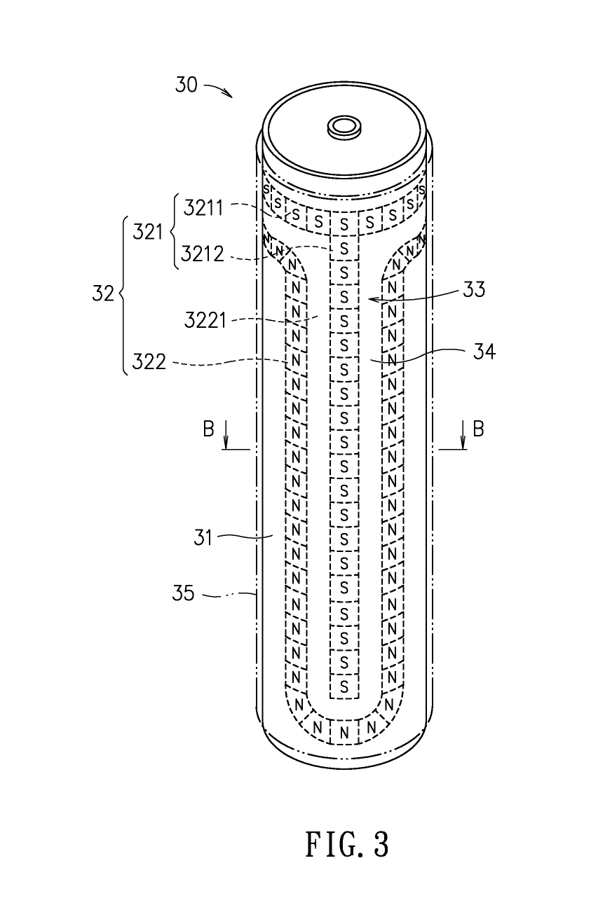

Referring to FIG. 3 to FIG. 5, the magnetron sputtering cathode 30 having a plurality of deposition zones according to the present invention comprises a hollow metal tube 31 and a plurality of magnet units 32 disposed inside the metal tube 31. The plurality of magnet units 32 comprises a plurality of first magnets 321 and a plurality of second magnets 322. The first magnets 321 and the second magnets 322 are disposed so that the orientations of magnetic poles thereof are opposite. In the present embodiment, the first magnets 321 are magnets with magnetic south poles (S in FIG. 3) oriented outwards from the metal tube 31 while the second magnets 322 are magnets with magnetic north poles (N in FIG. 3) oriented outwards from the metal tube 31. Alternatively, the first magnets 321 are magnets with magnetic north poles (N in FIG. 3) oriented outwards from the metal tube 31 while the second magnets 322 are magnets with magnetic south poles (S in FIG. 3) oriented outwards from the metal tube 31. In other words, the orientations of the magnetic poles of the first magnets 321 and the second magnets 322 oriented outwards from the metal tube 31 are opposite.

The plurality of second magnets construct a plurality of concave portions corresponding to the axial magnetic zones extending into the concave portions.

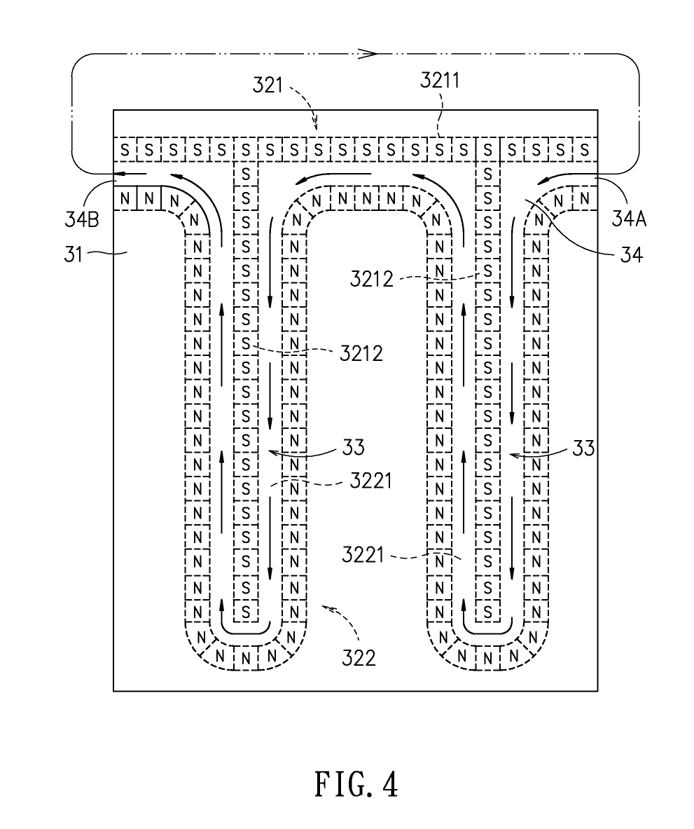

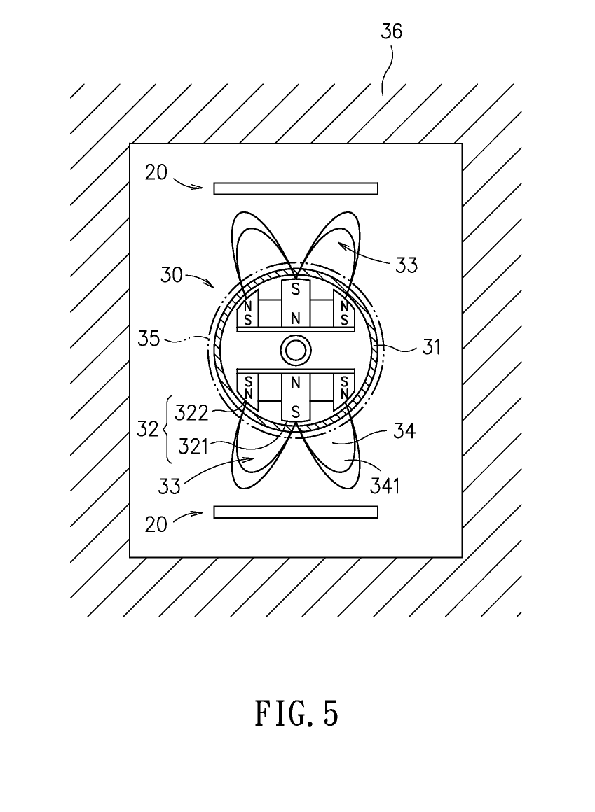

Referring to FIG. 3 and FIG. 4, the first magnets 321 construct a ring-shaped magnetic zone 3211 and a plurality of axial magnetic zones 3212. As shown in FIG. 4, there are two axial magnetic zones 3212. The ring-shaped magnetic zone 3211 is disposed around an axis of the metal tube 31 at one end. The two axial magnetic zones 3212 are disposed in parallel with the axis inside the metal tube 31. The second magnets 322 are disposed as a zigzag so that the second magnets 322 construct a plurality of concave portions 3221 corresponding to the axial magnetic zones 3212 extending into the concave portions 3221. In the present embodiment, the first magnets 321 construct two axial magnetic zones 3212. The two axial magnetic zones 3212 are disposed on both sides of the metal tube 31 and are symmetric respect to the center of the metal tube 31, as shown in FIG. 4. FIG. 3 only shows one of the sides. The first magnets 321 are a distance away from the second magnets 322 to form a magnetic tunnel 34 between the first magnets 321 and the second magnets 322. The magnetic tunnel 34 is a continuous closed loop. Each axial magnetic zone 3212 corresponds to the external second magnets 322 to form a U-shaped magnetic tunnel as a sputtering zone 33, as shown in FIG. 5. The two sputtering zones 33 are formed on both sides of the metal tube 31 and are symmetric respect to the center of the metal tube 31. The metal tube 31 is covered and surrounded by a target 35, which is driven by the metal tube 31 to rotate. The target 35 is a distance away from the metal tube 31 and corresponds to the two sputtering zones 33, each being provided with a substrate 20. The magnetron sputtering cathode 30, the substrate 20 are disposed in a reaction chamber 36. When a voltage is applied, electrons are driven by an electromagnetic field to move in a determined way along the magnetic tunnel 34, as indicated by the arrows in FIG. 4. In the region 341 of magnetic field lines, plasma is generated to sputter the target 35 so that the atoms/molecules of the target 35 are deposited on the two opposite substrates 20 to form thin films. Since both sides of the target 35 can be bombarded, the film deposition rate is enhanced. In the present invention, even though the ring-shaped magnetic zone 3211 disposed at one end of the metal tube 31 may lead to more target bombardment, the magnetic strength, the magnetic field distribution and the shape of target can be adjusted to modulate the magnetic field in the ring-shaped magnetic zone 3211.

It is noted that, one end of the magnetic tunnel 34 in FIG. 4 is an inlet 34A, while the other end is an outlet 34B. However, the magnetic tunnel 34 is actually a continuous closed loop. Moreover, the metal tube 31 can also be provided with three or more than three sputtering zones 33 for thin film deposition on multiple substrates 20.

Accordingly, the present invention provides a magnetron sputtering cathode comprising a plurality of magnet units disposed inside a metal tube for forming a plurality of sputtering zones on the surface of the metal tube so that multiple substrates can be coated at the same time to prevent the waste related to secondary plasma and reduce power and target loss. Meanwhile, the probability of depositing the sputtered target on the portion of the sputtering chamber at the back of the magnetron sputtering cathode is reduced and thus the efficiency of the target is increased.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A magnetron sputtering cathode, comprising:
a metal tube being hollow; and
a plurality of magnet units, disposed inside the metal tube for forming at least two sputtering zones on the surface of the metal tube;
wherein each of the plurality of sputtering zones is provided with a magnetic tunnel and the magnetic tunnels are configured to communicate with each other to form a loop.

2. The magnetron sputtering cathode as recited in claim 1, wherein the magnet units comprises a plurality of first magnets and a plurality of second magnets, the first magnets and the second magnets being disposed so that the orientations of magnetic poles thereof are opposite and a distance is between the first magnets and the second magnets to form a magnetic tunnel between the first magnets and second magnets.

3. The magnetron sputtering cathode as recited in claim 1, wherein
the plurality of first magnets construct a ring-shaped magnetic zone and at least two axial magnetic zones, the ring-shaped magnetic zone being disposed around an axis of the metal tube at one end and the axial magnetic zones being disposed in parallel with the axis inside the metal tube;
the plurality of second magnets construct a plurality of concave portions corresponding to the axial magnetic zones extending into the concave portions.

4. The magnetron sputtering cathode as recited in claim 3, wherein the plurality of second magnet are disposed as a zigzag.

5. The magnetron sputtering cathode as recited in claim 2, wherein either the first magnets or the second magnets are magnets with magnetic north poles oriented outwards from the metal tube while the others are magnets with magnetic south poles oriented outwards from the metal tube.

6. The magnetron sputtering cathode as recited in claim 1, wherein the surface of the metal tube is provided with two sputtering zones disposed symmetric with respect to the axis of the metal tube.
